(19) United States
(12) Patent Application Publication
(10) Pub. No.: US 2005/0138515 A1
(43) Pub. Date: Jun. 23, 2005

(54) Method and apparatus for co-verification of digital designs

(76) Inventors: Stanley M. Hyduke, Las Vegas, NV (US); Zbigniew Zalewski, Dzialdowo (PL)

Correspondence Address: David O' Reilly;Suite 200, 1800 Bridgegate Street, Westlake Village, CA, 91361, US

(21) Appl. No.: 10/703,146

(22) Filed: Nov. 5, 2003

(51) Int. Cl. G06F 11/00; G01R 31/28

(52) U.S. Cl. 714/741

(57) ABSTRACT

A method and apparatus for development and concurrent verification of digital designs including a combination of a microprocessor and discrete logic design blocks. The hardware/software design development and co-verification processing of digital designs is accelerated by placing the microprocessor in an FPGA device and logic circuits in an HDL simulator. The microprocessor and logic circuits are connected via a common bus and synchronization of both environments is achieved by using a simulator clock exclusively when both microprocessor and logic simulator need to communicate with each other. The system and method of the present invention provides a unique arrangement of a processor clocking scheme. An essential part of the invention is a clock switch responsive to the areas of RAM a processor is addressing and accordingly switching a clock signal to the processor from either a hardware clock generator or a software simulator.

### BACKGROUND OF THE INVENTION

1. Field of the Invention

This invention relates to verification of digital system designs that include a mixture of microprocessors and hardware description language (HDL) designs. More particularly, the invention relates to verification of application specific integrated circuits (ASIC) based designs that include microprocessors and HDL design blocks. Some large system designs for field programmable gate array (FPGA) devices can also effectively use the system and method of the proposed invention.

2. Background Information

The majority of today's digital system designs include some processors and HDL design blocks. This requires that both software and hardware design engineers work in parallel on the same design.

The current methodologies call for simulating the entire ASIC design, including the microprocessor operations, in software. This methodology requires very fast microprocessor models that can be executed by software simulators. The fast models are often written at behavioral level that do not provide precise data on system clocking and generally do not allow clocking of flip-flops on clock events.

Another drawback of the behavioral microprocessor models in system digital designs is that they simulate very slow. Still another shortcoming of these models is that the design needs to be simulated again once the structural microprocessor models are generated for the ASIC or the large FPGA implementation.

It is therefore one object of the present invention to provide a method and apparatus for fast verification of large system digital designs that include microprocessors and HDL designs.

Another object of the present invention is to provide apparatus for displaying true timing relationships between microprocessors and discrete logic generated signals.

A further object of the present invention is to allow for concurrent design verification of the same design by hardware designers and software programmers.

### BRIEF DESCRIPTION OF THE INVENTION

The purpose of the present invention is to provide a method and apparatus for accelerating the verification of digital system designs for applications specific integrated circuits and FPGA devices.

The present invention provides a method and apparatus for concurrent verification of digital designs such as ASIC or designs in FPGA devices. Co-verification of digital designs are accelerated by placing a microprocessor intellectual property (IP) core in an FPGA device and logic design circuits in an HDL simulator. The system uses a clock switch to provide clocking to the microprocessor according to particular areas of discrete RAM the microprocessor is trying to address. The clock switch selects clocking from a hardware clock generator or from a simulator containing HDL logic according to the area of RAM the microprocessor is addressing. Thus, ASIC designs that include microprocessors and HDL designs can be quickly and accurately verified.

The above and other objects, advantages, and novel features of the invention will be more fully understood from the following detailed description and the accompanying drawings, in which:

### BRIEF DESCRIPTION OF THE DRAWINGS

FIG. 1 is a block diagram illustrating the typical structure of an ASIC design.

FIG. 2 is a block diagram illustrating a computer system having a clock bridge for a selective clock application.

FIG. 3 is a table illustrating random access memory addressing space.

FIG. 4 is a block diagram illustrating clock switching architecture.

### DETAILED DESCRIPTION OF THE PREFERRED EMBODIMENT

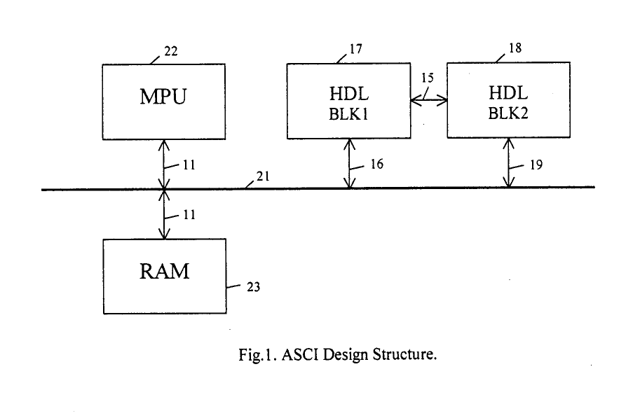

A typical ASIC or large FPGA system design 7 comprised of microprocessor unit (MPU) 22, random access memory (RAM) 23 and hardware logic blocks, such as blocks 17 and 18 is illustrated in the block diagram of FIG. 1. Microprocessor 22 executes a program residing in RAM 23 and provides processing data on local bus 11. Processor 22 spends most of its time processing-instructions provided by RAM 23. However, when needed, MPU 22 communicates also with HDL blocks 17 and 18. This kind of asynchronous communication of microprocessor 22 with hardware logic blocks 17 or 18 is called a transactional interface, and it is started either by processor 22 attempting to read or write into hardware logic blocks 17 or 18, or by an interrupt generated by one of hardware logic blocks 17 or 18 and sent over bus 11. Hardware logic block 17 is connected to bus 11 via bus 16 that may be a subset of bus 11. Similarly, hardware logic block 18 is connected to bus 11 via local bus 19 that may be a different subset of bus 11 than bus 16.

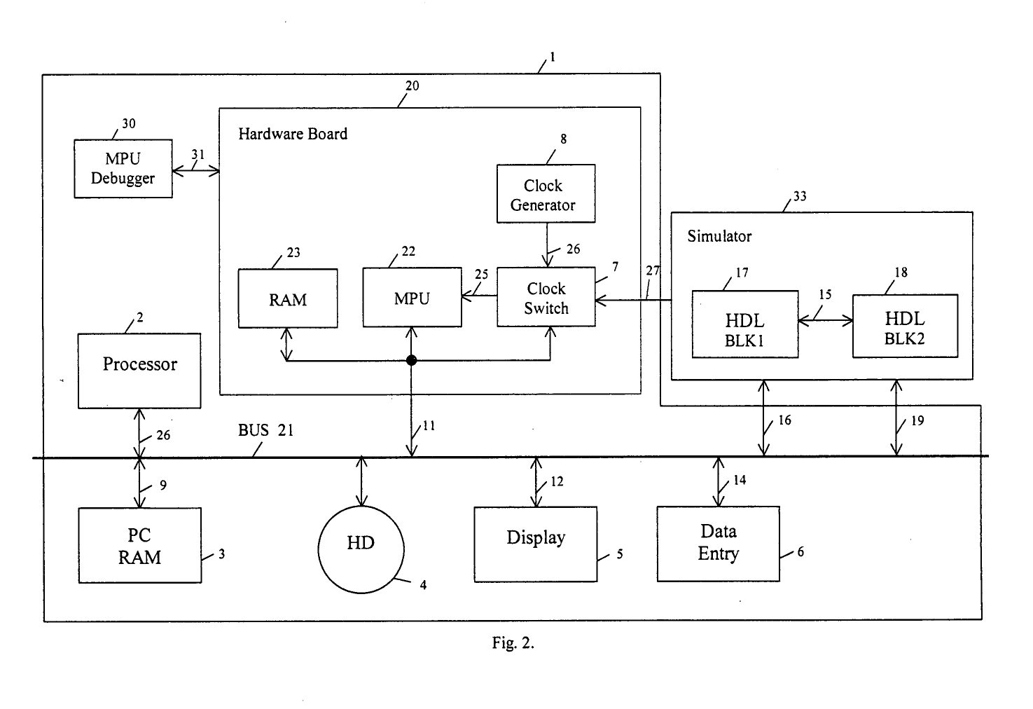

MPU 22 communicates with hardware logic blocks 17 and 18 on a transactional basis. Typically, in an ASIC device, bus 11 will be directly connected to the associated hardware logic blocks 17 and 18. However, because the invention splits the system design between hardware board 20 (FIG. 2) and HDL simulator 33, data on bus 11 is fed to HDL blocks 17 and 18 over bus 21, which is a peripheral component interconnect (PCI) bus in the case of a personal computer (PC), or similar bus for workstation applications.

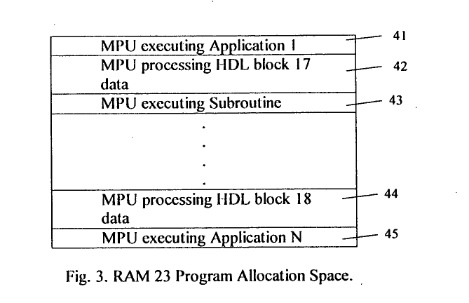

As shown in FIGS. 2 and 3, microprocessor 22 reads and writes data into RAM 23 over data bus 11. To provide faster execution of software subroutines, MPU 22 preferably resides in a field programmable gate array (FPGA) device such as a Stratix from Altera, Inc., or similar. Alatek, Inc. of Las Vegas, Nev. manufactures hardware boards such as hardware board 20, illustrated in FIG. 2 containing FPGA devices that can be downloaded with microprocessor 22 intellectual property (IP) core, turning the FPGA into microprocessor 22. Microprocessor board 20 also contains local RAM 23 for storing MPU 22 software programs, clock switch 7 and hardware clock generator 8.

Fast and easy development of HDL logic blocks 17 and 18 is facilitated, according to the current invention, by residing in software simulator 33 such as the Active-HDL simulator manufactured by Aldec, Inc. of Henderson, Nev., instead of being placed in hardware 20. The preferred connectivity of blocks related to microprocessor 22 is illustrated in FIG. 2, such as MPU 22, switch 7, clock generator 8 and RAM 23, and HDL blocks 17 and 18 located in simulator 33.

A block diagram of computer system 1 for debugging of MPU 22 processing software program residing in local RAM 23 and concurrent verification of hardware designs residing in simulator 33 is illustrated in FIG. 2. Computer system 1 can be a workstation such as a SunBlade 2000 manufactured by Sun Microsystems or a personal computer (PC) made by any number of manufacturers such as Dell or Hewlett-Packard, etc.

Computer system 1 is comprised of processor 2 such as an Intel Pentium IV, PC RAM 3, hard disk storage 4, display or monitor 5, and keyboard 6. PC RAM 3 is used for storing operating system and running concurrent application programs. Hard disk (HD) 4 is used for storing data generated by main PC processor 2 operating on PC RAM 3 data for storing simulator 33 data, MPU Debugger 30 data and when needed for storing MPU 22 programs and data. MPU Debugger 30 is the basic microprocessor 22 debugging tool used by software programmers for verification of software subroutine operations and troubleshooting of bugs. One of the most popular debuggers 30 is the GNU public domain debugger. It is comprised of a GCC compiler to compile the software subroutine for the specific microprocessor 22 and GDB debugger for viewing and controlling of microprocessor 22 operations. Debugger 30 architecture and applications are well established, and a number of vendors such as Altera, Inc. and Xilinx, Inc., both of San Jose, Calif., provide their derivatives of GNU debugger 30.

Because debugger 30 provides its own memory 23 ‘stub’, it has direct control over the microprocessor 22 operations, including its bus, internal flags and registers. As is customary, debugger 30 can stop microprocessor 22 instruction execution on breakpoints, specific memory addresses, etc.

PC RAM 3 is also used for storing design data such as HDL blocks 17 and 18 before they are loaded or mapped to local RAM 23 for simulation. Display or monitor 25 permits display of computer system 1 status and ASIC design information, and hardware 20 and simulator 33 related data. Data entry device 6 can be a keyboard, mouse device, or any other suitable device for entering design data and for causing selected actions by simulator 33, and processor 2.

Computer 1, hardware board 20 and simulator 33 operations are well known to those experts in the field. What is unique to the current invention disclosed herein is the arrangement of MPU 22 clocking scheme. MPU processor 22 operates under control of hardware clock provided on signal line 25. This hardware clock is generated by clock generator 8 and provided via signal line 26 to clock switch 7 that controls clocking on signal line 25.

MPU processor 22 executes a program residing in RAM 23. An example of such a program is shown in the table of FIG. 3. Clock switch 7 monitors data on bus 11 and any time it detects that MPU processor 22 attempts to address specific RAM locations that relate to servicing HDL logic blocks 17 or 18, such as RAM 23 program areas 42 or 44, it feeds software simulator 33 clocking on signal line 25 that it derives from signal line 27.

However, when MPU processor 22 executes software applications or subroutines such as 41, 43 or 45 (FIG. 3), processor 22 is controlled by a so called “hardware clock” signal produced by clock generator 8 and fed via signal line 26, clock switch 7 and signal line 25. Thus the essential part of the invention is that clock switch 7 is responsive to what areas of RAM 23 MPU processor 22 is addressing and switching accordingly MPU processor 22 clocking provided on signal line 25 to be either produced by clock generator 8 or simulator 33.

The operation of clock switch 7 is based on the “memory mapped input/output (I/O)” principle, which means that some of the I/O devices such as HDL blocks 17 and 18 have reserved RAM 23 address space and any time MPU processor 22 addresses these locations, a read or write operation to peripheral devices HDL blocks 17 or 18 is made.

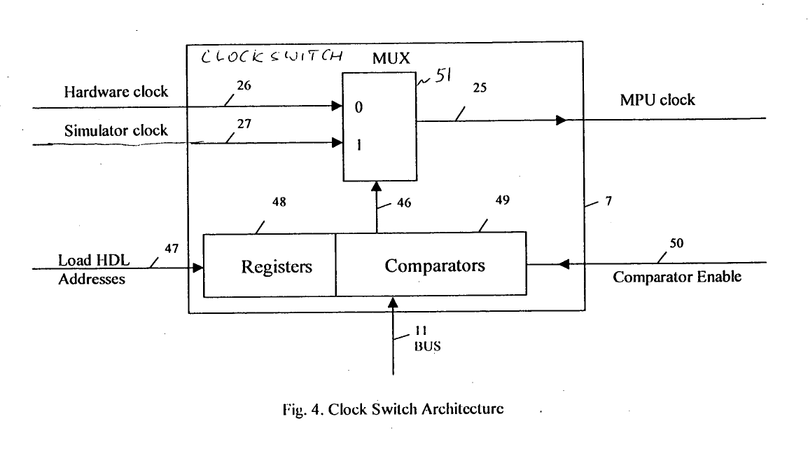

A detailed construction of clock switch 7 is illustrated in the block diagram of FIG. 4. A user selects via data entry 6, which RAM 23 memory locations will be reserved for servicing HDL design blocks 17 and 18 that reside in simulator 33. This data is fed into a set of registers 48 for future reference. The data provided on bus 11 is fed to comparator 49 that compares current bus 11 status with data stored in registers 48. Comparator 49 may be enabled for example by a read signal 50 generated by MPU processor 22 to eliminate transient comparison signals.

If comparator 49 finds a comparison between data on signal lines 11 and data stored previously in registers 48, a control signal is produced on signal line 46, which switches multiplexer (MUX) 51 to feed data from signal line 27 to signal line 25 that controls MPU processor 22 clock. As a result, MPU processor 22 is under control of simulator 33 clock provided on signal line 27. If there is no comparison between data on signal lines 11 and data in registers 48, comparator 49 will produce a controlling signal on signal line 46 that feeds data from signal line 26 to signal line 25, assuring that hardware clock controls MPU processor 22 operation.

Thus there has been disclosed a unique system for co-verification of ASIC or FPGA digital circuit designs that include a combination of a microprocessor and discrete logic design blocks. The invention provides a unique method and apparatus in the arrangement of MPU processor 22 clocking scheme. Clock switch 7 responsive to the areas of RAM 23 an MPU processor 22 addresses switches MPU processor 22 clocking to a signal produced either by a hardware clock generator 8 or a software simulator 33.

This invention is not to be limited by the embodiment shown in the drawings and described in the description which is given by way of example and not of limitation, but only in accordance with the scope of the appended claims.

1. A system for concurrent verification of a digital circuit design comprising;
a microprocessor (22);
a simulator (33);
random access memory (23) for storing processing software;
a hardware clock signal generator (8);
a clock switch (7) for selectively applying a clock signal (25) to said microprocessor (22) from said simulator (33) or from said hardware clock signal generator according to the areas of random access memory (23) being addressed by said microprocessor (22);
whereby concurrent verification of hardware and software design development can be made.

2. The system according to claim 1 including storing hardware descriptive language routines for said digital circuit design in said simulator (33).

3. The system according to claim 1 in which said clock switch comprises;
a multiplexer (51) for selecting a clock output to said microprocessor (22) from either said hardware clock generator (8) or said simulator (33) according to a comparison of data output to said random access memory;
a comparator (49) for comparing data on a bus connecting said microprocessor (22) and random access memory (23) with said reference data stored in said registers (48), and said comparator (49) switching the output of said multiplexer (51) according to the data comparison on said bus.

4. The system according to claim 3 whereby said clock switch (7) includes registers (48) connected to said comparator (49); said registers (48) storing addresses of hardware description language routines for said digital circuit design in said simulator (33);

5. The system according to claim 1 including an MPU debugger (30); connected to and controlling execution of instructions by said microprocessor (22).

6. The system according to claim 5 including a display (5) for displaying design data, and said MPU debugger (30) connected to said random access memory (23) and displaying the contents of said microprocessor (22) internal registers and said random access memory (23).

7. The system according to claim 6 wherein said display is common to said debugger (30) and said simulator (33) whereby data from both said debugger (30) and said simulator can be displayed on said common display.
